(19) United States
(12) Patent Application Publication
(10) Pub. No.: US 2026/0068130 A1
(43) Pub. Date: Mar. 5, 2026

(54) SEMICONDUCTOR STRUCTURE AND METHOD OF FORMING THE SAME

(71) Applicant: NANYA TECHNOLOGY CORPORATION, New Taipei City (TW)

(72) Inventor: Jhen-Yu TSAI, New Taipei City (TW)

(21) Appl. No.: 18/823,638

(22) Filed: Sep. 3, 2024

(51) Int. Cl. H10B 12/00

(52) U.S. Cl. CPC H10B 12/34; H10B 12/053

(57) ABSTRACT

The present disclosure provides a semiconductor structure. The semiconductor structure includes a substrate, a word line, and a dielectric layer. The word line is embedded in the substrate and includes a high work function layer and a low work function layer on the high work function layer, in which a work function of the high work function layer is larger than a work function of the low work function layer. The dielectric layer is between the substrate and the word line, in which the dielectric layer includes a first portion and a second portion. The first portion is between the substrate and the high work function layer. The second portion is between the substrate and the low work function layer, in which a thickness of the second portion is larger than a thickness of the first portion.

### BACKGROUND

### Field of Invention

The present disclosure relates to a semiconductor structure and a method of forming the same.

### Description of Related Art

Word lines are used in semiconductor structures, such as dynamic random-access memory (DRAM) devices. To improve the performance of the word line, the electrical field between the word line and other components disposed around the word line should be reduced in case the electrical field interferes with the performance of the word line. Moreover, a better word line should have smaller gate-induced drain leakage (GIDL). Although including the air gap beside the word line to replace the dielectric material may improve the gate-induced drain leakage, the drop of the dielectric constant of the material causes controlling the gate of the word line to be hard. Therefore, it is necessary to develop a novel word line and a novel method of forming the same.

### SUMMARY

The present disclosure provides a semiconductor structure. The semiconductor structure includes a substrate, a word line, and a dielectric layer. The word line is embedded in the substrate and includes a high work function layer and a low work function layer on the high work function layer, in which a work function of the high work function layer is larger than a work function of the low work function layer. The dielectric layer is between the substrate and the word line, in which the dielectric layer includes a first portion and a second portion. The first portion is between the substrate and the high work function layer. The second portion is between the substrate and the low work function layer, in which a thickness of the second portion is larger than a thickness of the first portion.

In some embodiments, a curved boundary is between the high work function layer and the first portion, and the high work function layer extends toward the first portion at the curved boundary.

In some embodiments, compared to the first portion, the second portion extends farther into the substrate.

In some embodiments, the second portion has a step-like sidewall facing the substrate.

In some embodiments, the dielectric layer further includes an extension portion between the high work function layer and the low work function layer.

In some embodiments, the dielectric layer further includes an extension portion on an upper surface of the low work function layer.

In some embodiments, the semiconductor structure further includes a nitride layer embedded in the substrate and on the word line, in which the dielectric layer further includes a third portion between the substrate and the nitride layer, and a thickness of the third portion is larger than the thickness of the first portion.

In some embodiments, the third portion includes a first layer on the substrate, a second layer on the first layer, and a third layer on the second layer, and a material of the second layer is different than materials of the first layer and the third layer.

In some embodiments, the third portion overlaps the word line from a top view.

In some embodiments, the nitride layer has a cross-section with an inverted T shape or a rectangular shape on the word line.

In some embodiments, the work function of the high work function layer is from 4.3 eV to 4.7 eV, and the work function of the low work function layer is from 4.0 eV to 4.4 eV.

The present disclosure also provides a method of forming a semiconductor structure. The method includes the following operations. A first part of an isolation layer is formed on a sidewall of a trench in a substrate. A high work function layer is formed in the trench and on the first part. A second part of the isolation layer is formed on the first part and the high work function layer. A low work function layer is formed on the high work function layer and the second part, in which a work function of the high work function layer is larger than a work function of the low work function layer. A portion of the second part and a portion of the first part beside the low work function layer are etched to form an opening beside the low work function layer. A portion of the substrate beside the opening is oxidized to transform the portion of the substrate into a third part of the isolation layer. A fourth part of the isolation layer is filled in the opening, in which a thickness of a portion of the isolation layer beside the low work function layer is larger than a thickness of a portion of the isolation layer beside the high work function layer.

In some embodiments, forming the second part further includes forming an extension portion of the second part on an upper surface of the high work function layer, and forming the low work function layer includes forming the low work function layer on the extension portion.

In some embodiments, the method further includes forming a fifth part of the isolation layer on the second part after forming the low work function layer and before etching the portion of the second part and the portion of the first part.

In some embodiments, the method further includes forming a nitride layer on the fifth part after filing the fourth part in the opening, in which a thickness of a portion of the isolation layer including the fifth part and beside the nitride layer is larger than the thickness of the portion of the isolation layer beside the high work function layer.

In some embodiments, the method further includes the following operations. A sacrificial layer is formed on the low work function layer after forming the low work function layer and before forming the fifth part, in which forming the fifth part further includes forming an extension portion of the fifth part on an upper surface of the sacrificial layer. The extension portion and the sacrificial layer are removed to form an opening with an inverted T-shaped cross-section on the low work function layer before etching the portion of the second part and the portion of the first part.

In some embodiments, filling the fourth part includes filling the fourth part on an upper surface of the low work function layer.

In some embodiments, the method further includes etching a portion of the first part before forming the high work function layer.

In some embodiments, a material of the first part and a material of the second part are different.

In some embodiments, a material of the first part and a material of the second part are the same.

### BRIEF DESCRIPTION OF THE DRAWINGS

The present disclosure can be more fully understood by reading the following detailed description of the embodiments, with reference made to the accompanying figures as follows.

FIG. 1 is a portion of a top view of a semiconductor structure according to some embodiments of the present disclosure.

FIGS. 2A, 2B, 2C, and 2D are cross-sectional views of a portion of the semiconductor structure along the line A-A of FIG. 1 according to some different embodiments of the present disclosure.

FIG. 3 is a cross-sectional view of a portion of the semiconductor structure along the line B-B of FIG. 2A, FIG. 2B, FIG. 2C, or FIG. 2D according to some embodiments of the present disclosure.

FIG. 4 is a cross-sectional view of a portion of a semiconductor structure according to some comparative embodiments of the present disclosure.

FIG. 5 is a flow chart of a method of forming a semiconductor structure according to some embodiments of the present disclosure.

FIGS. 6 to 18 are cross-sectional views of the structures in the stages of forming the semiconductor structure according to some embodiments of the present disclosure.

### DETAILED DESCRIPTION

To make the description of the present disclosure detailed and complete, the following is an illustrative description of the aspects of the embodiments. This is not to limit the embodiments of the present disclosure to only one form. The embodiments of the present disclosure may be combined or substituted with each other when it is beneficial, and other embodiments may be added without further explanation.

In addition, spatially relative terms, such as below and above, etc., may be used in the present disclosure to describe the relationship between one element (or feature) to another element (or feature) in the figures. In addition to the orientation depicted in the figures, spatially relative terms are intended to encompass different orientations of the device in use or in operation. For example, the device may be oriented otherwise (e.g., rotated at 90 degrees), and the spatially relative terms can be interpreted accordingly. In the present disclosure, unless otherwise indicated, the same element numbers in different figures refer to the same or similar elements formed from the same or similar materials by the same or similar methods.

The terms “around”, “approximately”, “nearly”, “basically”, “substantially”, etc., used in the present disclosure include the stated values (or characteristics) and a deviation of the stated values (or characteristics) understood by one skilled in the art. For example, considering the errors of the values (or characteristics), these terms may indicate the values within one or more standard deviations (e.g., the values within ±30%, ±20%, ±15%, ±10%, or ±5%), or may indicate the characteristics including the deviation from the practical operation (e.g., the “substantially parallel” may indicate close to parallel in practical, rather than a perfect ideally parallelism). Furthermore, it is possible to select an acceptable range of the deviation according to the nature of the measurement or other properties, instead of applying only one single deviation range to all the values (or characteristics).

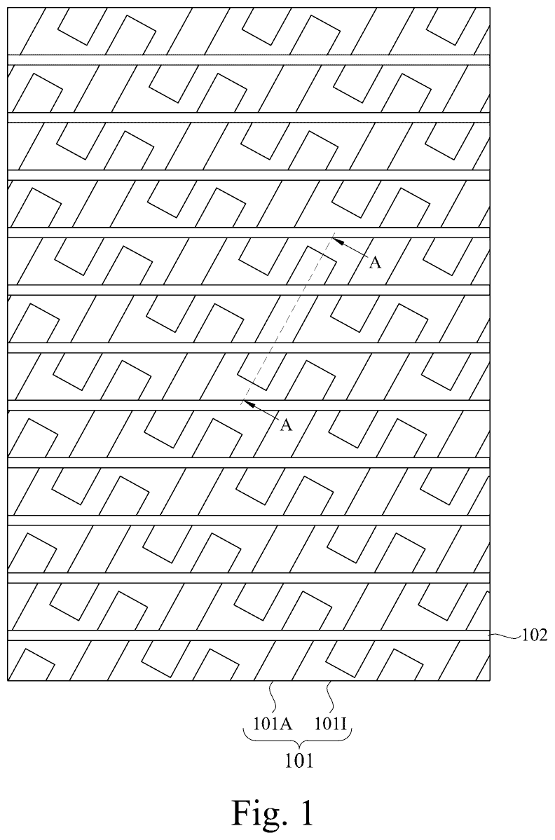

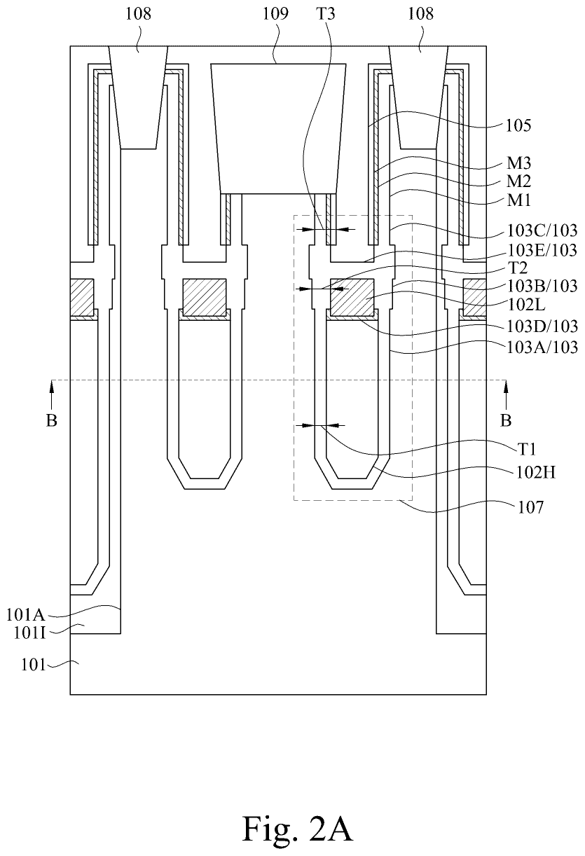

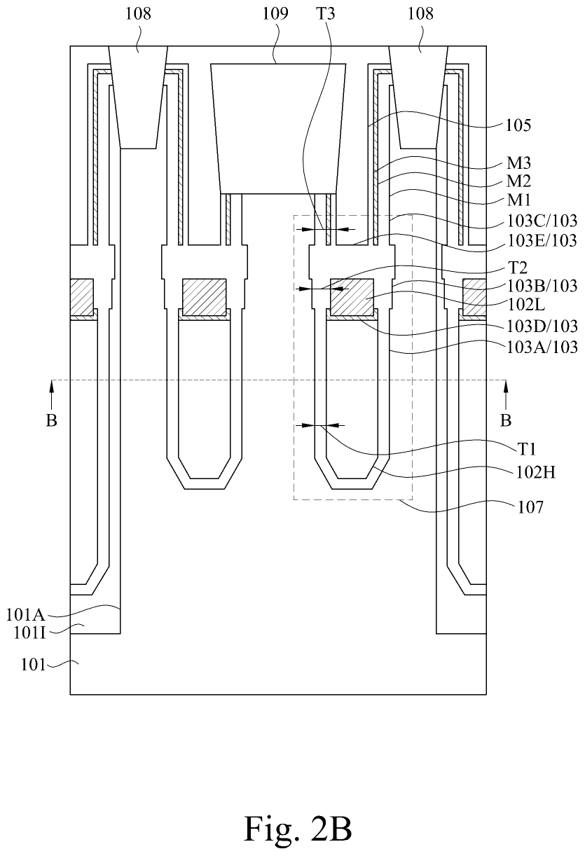

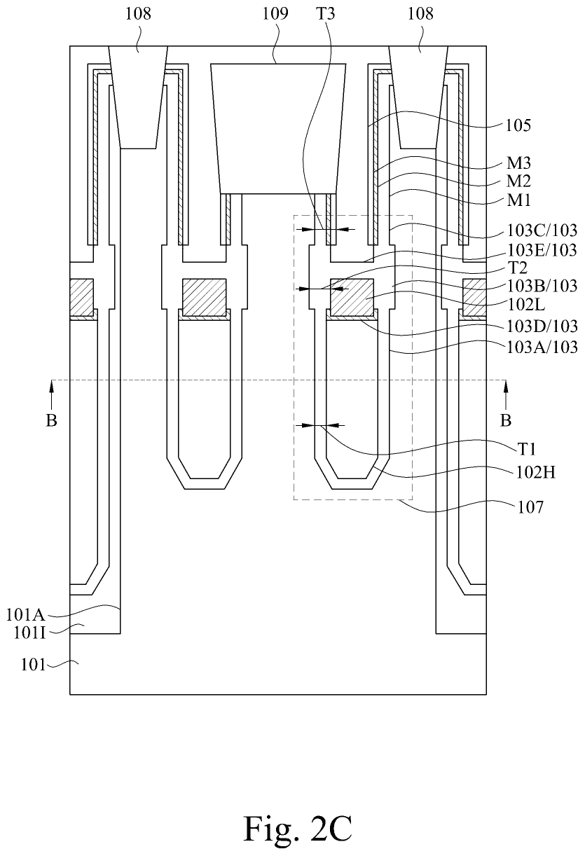

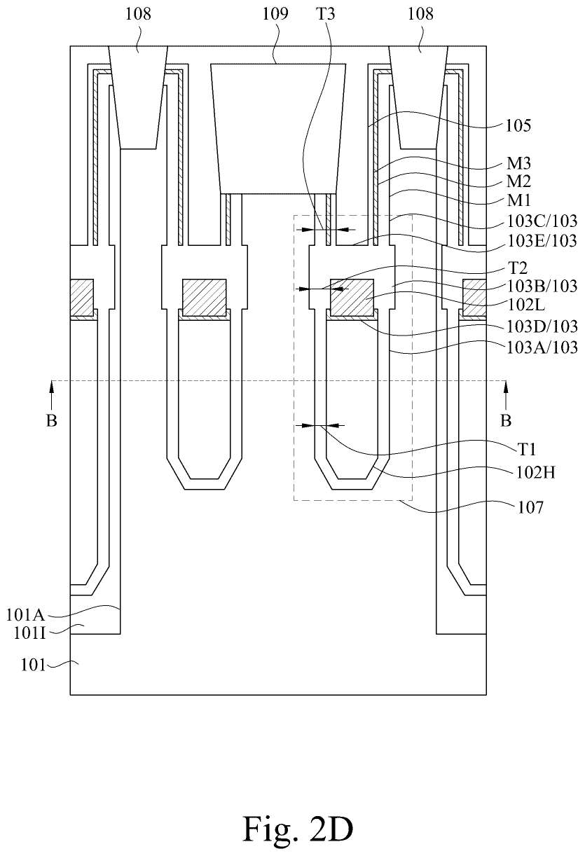

The present disclosure provides a semiconductor structure, as shown in FIGS. 1 to 3, in which FIGS. 2A, 2B, 2C, and 2D are the first, the second embodiment, the third embodiment, and the fourth embodiment of the semiconductor structure respectively. The semiconductor structure includes a substrate 101, a word line 102, and a dielectric layer 103. The word line 102 is embedded in the substrate 101 and includes a high work function layer 102H and a low work function layer 102L on the high work function layer 102H, in which a work function of the high work function layer 102H is larger than a work function of the low work function layer 102L. The dielectric layer 103 is between the substrate 101 and the word line 102, in which the dielectric layer 103 includes a first portion 103A and a second portion 103B. The first portion 103A is between the substrate 101 and the high work function layer 102H. The second portion 103B is between the substrate 101 and the low work function layer 102L, in which a thickness T2 of the second portion 103B is larger than a thickness T1 of the first portion 103A. By having the thickness T2 of the second portion 103B beside the low work function layer 102L being larger than the thickness T1 of the first portion 103A beside the high work function layer 102H, the gate-induced drain leakage (GIDL) is reduced, and the distances between the gate of the word line and the other components (e.g., the cell contact 108 that may be disposed above the word line, and so on) are receded to reduce the influence of the electrical fields located between the word line and the other components to reduce the electrical fields interfering with the performance of the word line. Moreover, without using the air gap to replace the dielectric layer 103, the drop of the dielectric constant caused by the air gap is avoided to prevent reducing the control to the gate of the word line 102 when operating the word line 102. Next, the semiconductor structure is described in detail with the embodiments of the present disclosure.

Firstly, the substrate 101 is discussed. In some embodiments, the substrate 101 is a semiconductor substrate, such as a silicon substrate, and may include any suitable semiconductor material. In some embodiments, the semiconductor material includes an elemental semiconductor material, for example, carbon, monocrystalline silicon, polycrystalline silicon, amorphous silicon, germanium, tin, sulfur, selenium, tellurium, or the like; a compound semiconductor material, for example, silicon carbide, nitride boron, aluminum nitride, gallium nitride, gallium phosphide, gallium arsenide, indium phosphide, indium arsenide, indium antimonide, zinc oxide, or the like; an alloy semiconductor material, for example, SiGe, AlGaAs, InGaAs, InGaP, AlInAs, GaAsP, AlGaN, InGaN, AlGaInP, or the like; or combinations thereof.

In some embodiments, the substrate 101 includes an isolation region 1011 and active regions 101A, in which the active regions 101A are separated from each other by the isolation region 1011, as shown in FIG. 1. In some embodiments, each one of the active regions 101A includes an N-type conducting dopant or a P-type conducting dopant. In some embodiments, the isolation region 1011 includes an electrical isolation material, for example, silicon oxide.

Secondly, the word line 102 is discussed. The word line 102 is embedded in the substrate 101 and includes the high work function layer 102H and the low work function layer 102L on the high work function layer 102H, in which the work function of the high work function layer 102H is larger than the work function of the low work function layer 102L. Compared to the word line excluding the high work function layer 102H and including only the low work function layer 102L, when the word line 102 further includes the high work function layer 102H, the gate-induced drain leakage can be reduced. In some embodiments, the work function of the high work function layer 102H is preferably from 4.3 eV to 4.7 eV, for example, 4.3 eV, 4.4 eV, 4.5 eV, 4.6 eV, or 4.7 eV, and the work function of the low work function layer 102L is preferably from 4.0 eV to 4.4 eV, for example, 4.0 eV, 4.1 eV, 4.2 eV, 4.3 eV, or 4.4 eV. In some embodiments, the low work function layer 102L is used as the gate. In some embodiments, the semiconductor structure may further include a contact structure (not drawn) electrically connecting the low work function layer 102L and the high work function layer 102H.

In some embodiments, the high work function layer 102H and the low work function layer 102L are conductive. In some embodiments, the high work function layer 102H is a metal layer, for example, including tungsten. In some embodiments, the low work function layer 102L is a silicon-containing conductive layer, for example, including polysilicon. In some embodiments, the word line 102 extends along a direction on the substrate 101 to across different active regions 101A. In some embodiments, the high work function layer 102H and the low work function layer 102L extend continuously between the sidewalls of the dielectric layer 103. In some embodiments, the number of the word line 102 is plural.

Thirdly, the dielectric layer 103 is discussed. The dielectric layer 103 is between the substrate 101 and the word line 102 to provide the electrical isolation for the word line 102 from other electrical components in the substrate 101. The dielectric layer 103 includes the first portion 103A between the substrate 101 and the high work function layer 102H and the second portion 103B between the substrate 101 and the low work function layer 102L, in which the thickness T2 of the second portion 103B is larger than the thickness T1 of the first portion 103A. The thicker second portion 103B of the dielectric layer 103 decreases the electrical fields located between the word line 102 and other components that may be disposed above the high work function layer 102H and decreases the gate-induced drain leakage. In some embodiments, the first portion 103A and the second portion 103B of the dielectric layer 103 respectively include dielectric materials, for example, silicon oxide, silicon nitride, or a combination thereof.

In some embodiments, compared to the first portion 103A of the dielectric layer 103, the second portion 103B of the dielectric layer 103 extends farther into the substrate 101. In some embodiments, the dielectric layer 103 has a step-like sidewall facing the substrate 101 and in contact with the substrate 101. In some embodiments, the dielectric layer 103 has a portion of the sidewall extending stepwise from above the upper surface of the low work function layer 102L to below the upper surface of the low work function layer 102L (see FIGS. 2A and 2B). In some embodiments, the dielectric layer 103 has a portion of the sidewall extending straight from above the upper surface of the low work function layer 102L to below the upper surface of the low work function layer 102L (see FIGS. 2C and 2D). In some embodiments, the second portion 103B of the dielectric layer 103 has a step-like sidewall facing the substrate 101 and in contact with the substrate 101. In some embodiments, the second portion 103B of the dielectric layer 103 is in contact with at least a portion of the side surface of the low work function layer 102L.

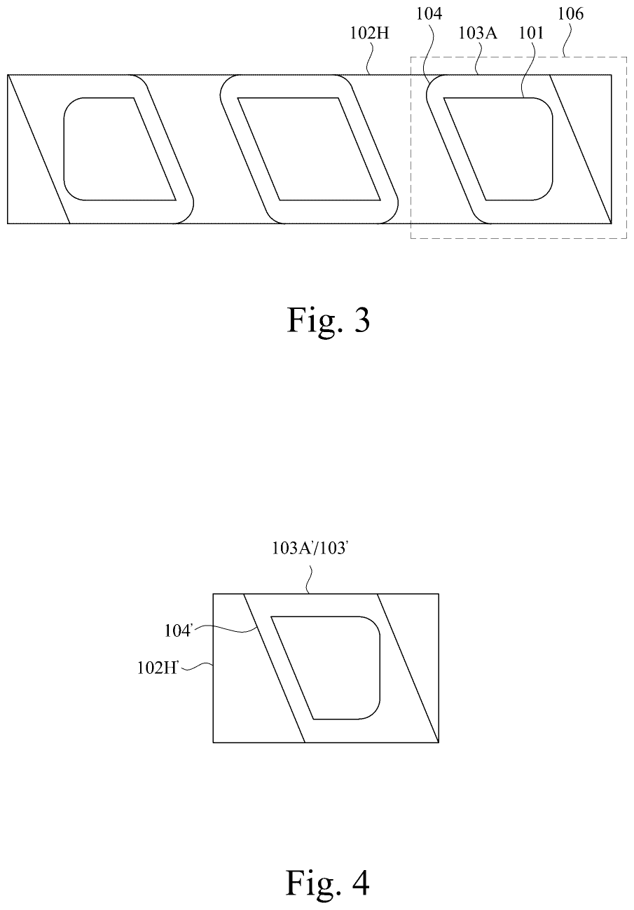

In some embodiments, a curved boundary 104 is between the high work function layer 102H and the first portion 103A of the dielectric layer 103, as shown in FIG. 3, and the high work function layer 102H extends into the first portion 103A of the dielectric layer 103 at the curved boundary 104. By extending into the first portion 103A of the dielectric layer 103, the high work function layer 102H increases the control to the gate and decreases the resistance of the word line 102.

In some comparative embodiments of FIG. 4 which is the corresponding view of the dashed line box 106 shown in FIG. 3, when the high work function layer 102H′ does not extend into the first portion 103A′ of the dielectric layer 103′ at the boundary 104′ between the high work function layer 102H′ and the first portion 103A′, there is no extended high work function layer 102H′ to improve the control to the gate and to decrease the resistance of the word line.

In some embodiments, the dielectric layer 103 may further include a third portion 103C on the second portion 103B to provide the electrical isolation. In some embodiments, a thickness T3 of the third portion 103C of the dielectric layer 103 is larger than the thickness T1 of the first portion 103A of the dielectric layer 103. The thicker third portion 103C of the dielectric layer 103 decreases the electrical fields located between the word line 102 and other components that may be disposed above the low work function layer 102L and prevents the dielectric layer 103 from being consumed too much when forming other components disposed above the low work function layer 102L. In some embodiments, compared to the third portion 103C of the dielectric layer 103, the second portion 103B of the dielectric layer 103 extends farther into the substrate 101. In some embodiments, the third portion 103C of the dielectric layer 103 extends further to cover an upper surface of the substrate 101. In some embodiments, the third portion 103C of the dielectric layer 103 includes a dielectric material, for example, silicon oxide, silicon nitride, or a combination thereof.

In some embodiments, the third portion 103C of the dielectric layer 103 includes a first layer M1, a second layer M2, and a third layer M3, the second layer M2 is between the first layer M1 and the third layer M3, and the second layer M2 is different than the first layer M1 and the third layer M3. In some embodiments, the second layer M2 is separated from the word line 102. In some embodiments, a virtual extension line of the boundary of the second layer M2 is aligned with the side surface of the low work function layer 102L. In some embodiments, the third portion 103C of the dielectric layer 103 (e.g., the third layer M3) overlaps the word line 102 from the top view of seeing the semiconductor structure.

In some embodiments, the semiconductor structure may further include a nitride layer 105 embedded in the substrate 101 and on the word line 102, in which the third portion 103C of the dielectric layer 103 is between the substrate 101 and the nitride layer 105. In some embodiments, the first layer M1 of the third portion 103C surrounds the second layer M2 of the third portion 103C, and the third layer M3 of the third portion 103C surrounds the nitride layer 105. In some embodiments, the nitride layer 105 has a cross-section with an inverted T shape (see FIGS. 2A and 2C) or a rectangular shape (see FIGS. 2B and 2D) on the word line 102. In some embodiments, the nitride layer 105 has a bottom portion and a top portion on the bottom portion, in which a width of the bottom portion is larger than a width of the top portion (see FIGS. 2A and 2C). In some embodiments, the nitride layer 105 has a consistent width (see FIGS. 2B and 2D). In some embodiments, the dielectric layer 103 is continuous along the word line 102 to the nitride layer 105. In some embodiments, there is substantially no air gap between the dielectric layer 103 and the word line 102 and the nitride layer 105.

In some embodiments, the dielectric layer 103 may further include an extended fourth portion 103D of the dielectric layer 103 between the high work function layer 102H and the low work function layer 102L. The fourth portion 103D of the dielectric layer 103 prevents the high work function layer 102H from reacting with the low work function layer 102L. In some embodiments, the fourth portion 103D of the dielectric layer 103 covers the whole upper surface of the high work function layer 102H and the whole lower surface of the low work function layer 102L. In some embodiments, the fourth portion 103D of the dielectric layer 103 may extend to cover a portion of the side surface of the low work function layer 102L. In some embodiments, the fourth portion 103D of the dielectric layer 103 includes a dielectric material, for example, silicon oxide, silicon nitride, or a combination thereof.

In some embodiments, the dielectric layer 103 may further include an extended fifth portion 103E of the dielectric layer 103 on the upper surface of the low work function layer 102L, and in some embodiments, the fifth portion 103E of the dielectric layer 103 covers the whole upper surface of the low work function layer 102L. In some embodiments, the fifth portion 103E of the dielectric layer 103 includes a dielectric material, for example, silicon oxide, silicon nitride, or a combination thereof.

In some embodiments, the materials of the fourth portion 103D of the dielectric layer 103 and the second layer M2 of the third portion 103C of the dielectric layer 103 are the same. In some embodiments, the materials of the first portion 103A of the dielectric layer 103, the second portion 103B of the dielectric layer 103, the first layer M1 and the third layer M3 of the third portion 103C of the dielectric layer 103, and the fifth portion 103E of the dielectric layer 103 are the same. In some embodiments, the materials of the first portion 103A of the dielectric layer 103, the second portion 103B of the dielectric layer 103, the first layer M1 and the third layer M3 of the third portion 103C of the dielectric layer 103, and the fifth portion 103E of the dielectric layer 103 are different than the materials of the fourth portion 103D of the dielectric layer 103 and the second layer M2 of the third portion 103C of the dielectric layer 103.

In some embodiments, the semiconductor structure may further include a cell contact 108 and a bit line 109 disposed on the substrate 101 above the word line 102. In some embodiments, the semiconductor structure further includes a source (not drawn) and a drain (not drawn) respectively on the two sides of the gate of the word line 102.

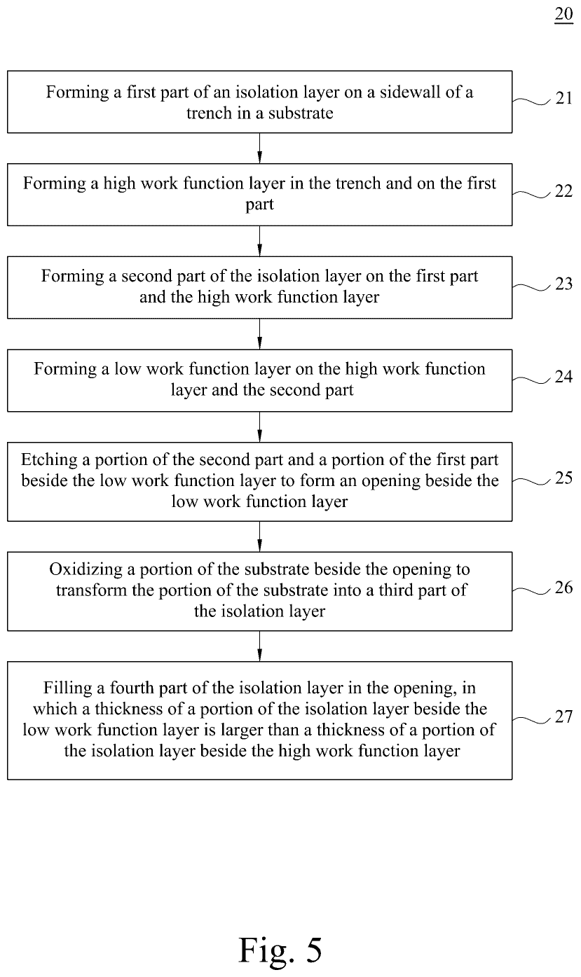

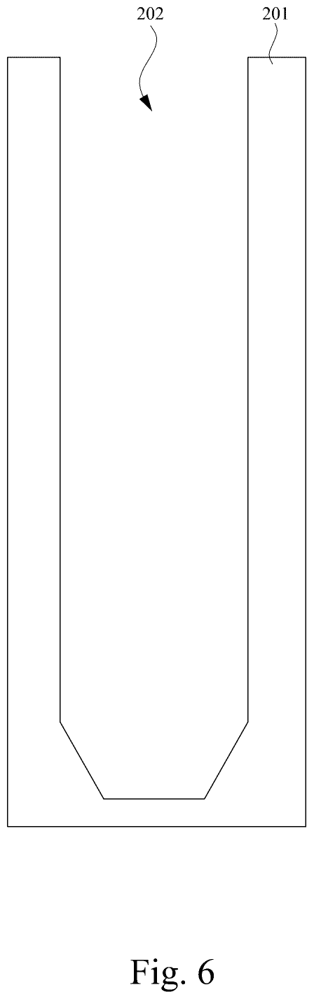

The present disclosure also provides a method 20 of forming the semiconductor structure described above. The method 20 includes an operation 21 to an operation 27, as shown in FIG. 5. When reading FIG. 5, please also refer to FIGS. 1 to 3 and 6 to 18 for more details, in which FIGS. 6 to 18 are corresponding enlarged views of the dashed line box 107 shown in FIG. 2A, FIG. 2B, FIG. 2C, or FIG. 2D. The operation 21 includes forming a first part 203A of an isolation layer 203 on a sidewall of a trench 202 in a substrate 201. The operation 22 includes forming a high work function layer 205 in the trench 202 and on the first part 203A. The operation 23 includes forming a second part 203B of the isolation layer 203 on the first part 203A and the high work function layer 205. The operation 24 includes forming a low work function layer 206 on the high work function layer 205 and the second part 203B, in which a work function of the high work function layer 205 is larger than a work function of the low work function layer 206. The operation 25 includes etching a portion of the second part 203B and a portion of the first part 203A beside the low work function layer 206 to form an opening 209 beside the low work function layer 206. The operation 26 includes oxidizing a portion of the substrate 201 beside the opening 209 to transform the portion of the substrate 201 into a third part 203C of the isolation layer 203. The operation 27 includes filling a fourth part 203D of the isolation layer 203 in the opening 209, in which a thickness T2 of a portion of the isolation layer 203 beside the low work function layer 206 is larger than a thickness T1 of a portion of the isolation layer 203 beside the high work function layer 205. Next, the method 20 is described in detail with the embodiments of the present disclosure.

See FIG. 6. In some embodiments, before forming the first part 203A of the isolation layer 203, the method 20 may further include forming the trench 202 in the substrate 201 by any suitable etching method, for example, by a dry etching method or a wet etching method. The trench 202 will be filled with the word line including the high work function layer 205 and the low work function layer 206 in the following operation. In some embodiments, the substrate 201 is a semiconductor substrate, such as a silicon substrate, and may include any suitable semiconductor material. In some embodiments, the semiconductor material includes an elemental semiconductor material, for example, carbon, monocrystalline silicon, polycrystalline silicon, amorphous silicon, germanium, tin, sulfur, selenium, tellurium, or the like; a compound semiconductor material, for example, silicon carbide, nitride boron, aluminum nitride, gallium nitride, gallium phosphide, gallium arsenide, indium phosphide, indium arsenide, indium antimonide, zinc oxide, or the like; an alloy semiconductor material, for example, SiGe, AlGaAs, InGaAs, InGaP, AlInAs, GaAsP, AlGaN, InGaN, AlGaInP, or the like; or combinations thereof.

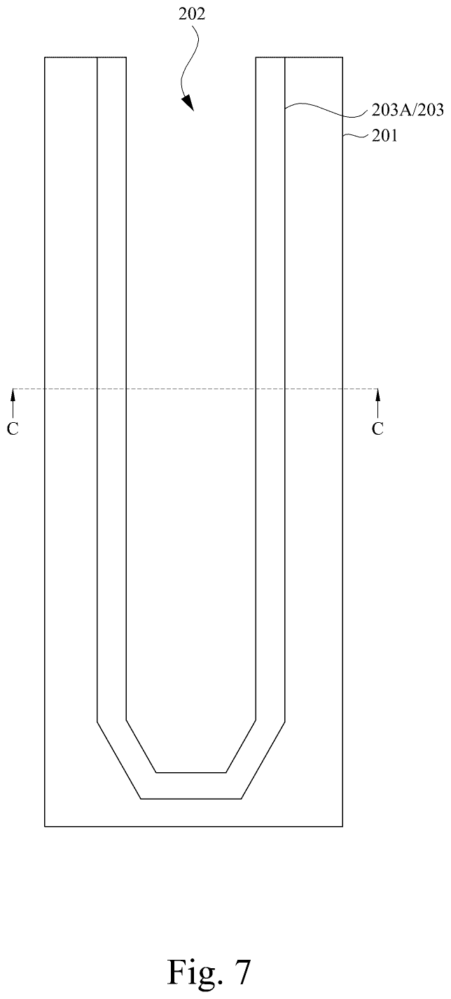

See FIG. 7. The operation 21 includes forming the first part 203A of the isolation layer 203 on the sidewall of the trench 202 by any suitable deposition method, for example, by a chemical vapor deposition or a physical vapor deposition. The first part 203A of the isolation layer 203 provides the electrical isolation for the high work function layer 205 and the low work function layer 206 (formed in the following operations) from other electrical components in the substrate 201. It is noted that a portion of the first part 203A of the isolation layer 203 may be removed in the following operations to form the isolation layer 203 having a thicker thickness beside the low work function layer 206 in the following operations. In some embodiments, the first part 203A of the isolation layer 203 is formed to cover the whole surface of the trench 202. In some embodiments, the first part 203A of the isolation layer 203 is conformally formed along the surface of the trench 202. In some embodiments, the first part 203A of the isolation layer 203 is formed further on the upper surface of the substrate 201 outside the trench 202 (not drawn). In some embodiments, the first part 203A of the isolation layer 203 includes a dielectric material, for example, silicon oxide, silicon nitride, or a combination thereof.

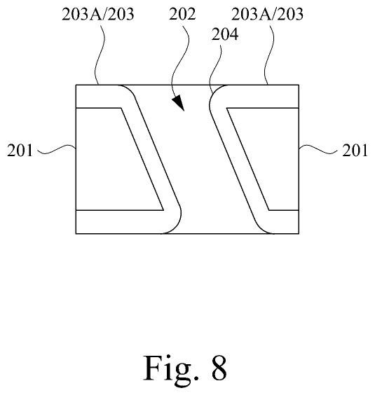

See FIG. 8, in which FIG. 8 is a portion of a cross-sectional view of FIG. 7 along the line C-C of FIG. 7. In some embodiments, before forming the high work function layer 205 in the operation 22, the method 20 may further include etching a portion of the first part 203A of the isolation layer 203, and after etching the portion of the first part 203A of the isolation layer 203, the first part 203A of the isolation layer 203 has a curved exposed sidewall 204 and the trench 202 extends into the first part 203A of the isolation layer 203 at the curved exposed sidewall 204. By etching the portion of the first part 203A of the isolation layer 203, the extended trench 202 at the curved exposed sidewall 204 allows more material (e.g., the high work function layer 205) to be filled in the trench 202 in the following operations, thereby increasing the control to the gate of the word line and decreasing the resistance of the word line. For example, when the high work function layer 205 is formed in the trench 202 and on the first part 203A of the isolation layer 203 in the operation 22, a curved boundary will be formed between the high work function layer 205 and the first part 203A of the isolation layer 203, and the high work function layer 205 extends into the first part 203A of the isolation layer 203 at the curved boundary, which is substantially the same as described in FIG. 3. In some embodiments, etching the portion of the first part 203A of the isolation layer 203 is preferably performed by a wet etching method, for example, preferably using an etchant including a diluted hydrofluoric acid. In some embodiments, the diluted hydrofluoric acid includes hydrogen fluoride and water, and a volume ratio or a flow rate ratio of the hydrogen fluoride to the water is preferably from 1:100 to 1:500, for example, 1:100, 1:200, 1:300, 1:400, or 1:500.

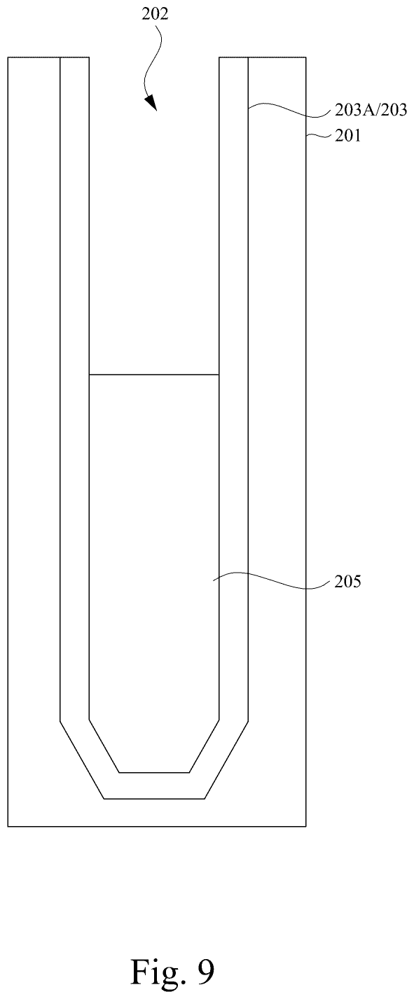

See FIG. 9. The operation 22 includes forming the high work function layer 205 of the word line in the bottom of the trench 202 and on the first part 203A of the isolation layer 203 by any suitable deposition method, for example, by a chemical vapor deposition method or a physical vapor deposition method. Compared to the word line excluding the high work function layer 205 and including only the low work function layer 206 (formed in the following operations), when the word line further includes the high work function layer 205, the gate-induced drain leakage can be reduced. In some embodiments, the work function of the high work function layer 205 is preferably from 4.3 eV to 4.7 eV, for example, 4.3 eV, 4.4 eV, 4.5 eV, 4.6 eV, or 4.7 eV. In some embodiments, the high work function layer 205 is conductive. In some embodiments, the high work function layer 205 is a metal layer, for example, including tungsten. In some embodiments, after forming the high work function layer 205, the bottom of the trench 202 is completely filled with the high work function layer 205.

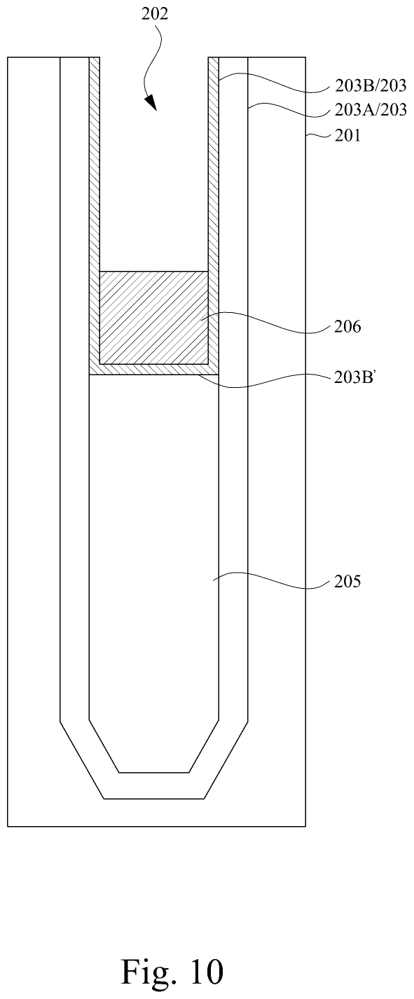

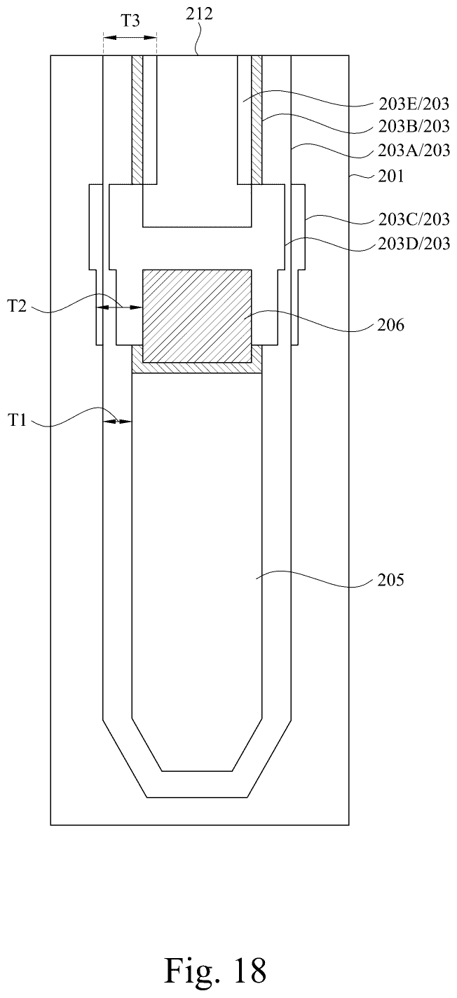

See FIG. 10. The operation 23 includes forming the second part 203B of the isolation layer 203 on the first part 203A of the isolation layer 203 and the high work function layer 205 by any suitable deposition method, for example, by a chemical vapor deposition or a physical vapor deposition. In addition to providing the electrical isolation, the second part 203B of the isolation layer 203 disposed above the high work function layer 205 increases the thickness of the isolation layer 203 above the high work function layer 205, thereby decreasing the electrical fields located between the word line and other components that may be disposed above the high work function layer 205. Moreover, forming the second part 203B of the isolation layer 203 decreases the space to form the low work function layer 206 in the trench 202 in the following operations, thereby providing more space beside the low work function layer 206 to form the isolation layer 203 having a larger thickness beside the low work function layer 206 in the following operations. When the thickness (e.g., the thickness T2 shown in FIG. 18) of the isolation layer 203 beside the low work function layer 206 is larger than the thickness (e.g., the thickness T1 shown in FIG. 18) of the isolation layer 203 beside the high work function layer 205, the gate-induced drain leakage can be decreased.

In some embodiments, forming the second part 203B of the isolation layer 203 includes forming an extension portion 203B′ of the second part 203B of the isolation layer 203 on an upper surface of the high work function layer 205, and in some embodiments, the second part 203B of the isolation layer 203 covers the whole upper surface of the high work function layer 205. The extension portion 203B′ of the second part 203B of the isolation layer 203 prevents the high work function layer 205 from reacting with the low work function layer 206 formed on the high work function layer 205 in the following operations. In some embodiments, the second part 203B of the isolation layer 203 is conformally formed along the exposed surfaces of the first part 203A of the isolation layer 203 and the high work function layer 205. In some embodiments, the second part 203B of the isolation layer 203 is formed further on the first part 203A of the isolation layer 203 on the upper surface of the substrate 201 outside the trench 202 (not drawn). In some embodiments, the second part 203B of the isolation layer 203 includes a dielectric material, for example, silicon oxide, silicon nitride, or a combination thereof. In some embodiments, the material of the first part 203A of the isolation layer 203 and the material of the second part 203B of the isolation layer 203 are different. In some embodiments, the material of the first part 203A of the isolation layer 203 and the material of the second part 203B of the isolation layer 203 are the same.

See FIG. 10. The operation 24 includes forming the low work function layer 206 of the word line on the high work function layer 205 and the second part 203B of the isolation layer 203 by any suitable deposition method, for example, by a chemical vapor deposition method or a physical vapor deposition method, in which the work function of the high work function layer 205 is larger than the work function of the low work function layer 206. The low work function layer 206 may be used as the gate. In some embodiments, the work function of the low work function layer 206 is preferably from 4.0 eV to 4.4 eV, for example, 4.0 eV, 4.1 eV, 4.2 eV, 4.3 eV, or 4.4 eV. In some embodiments, the low work function layer 206 is conductive. In some embodiments, the low work function layer 206 is a silicon-containing conductive layer, for example, including polysilicon. In some embodiments, forming the low work function layer 206 includes forming the whole lower surface of the low work function layer 206 on the extension portion 203B′ of the second part 203B of the isolation layer 203. In some embodiments, the method 20 may further include forming a contact structure (not drawn) electrically connecting the high work function layer 205 and the low work function layer 206.

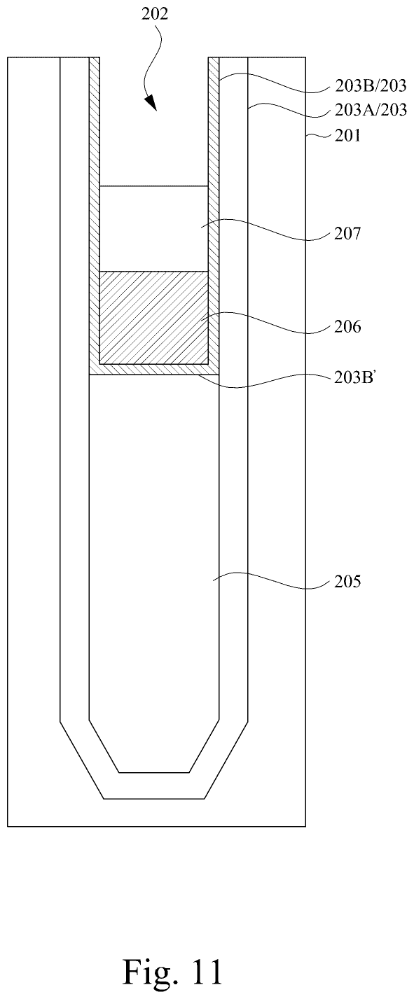

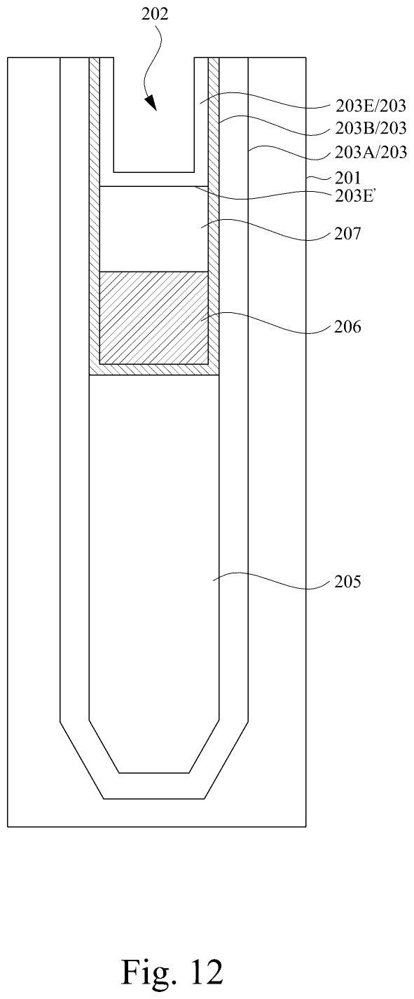

See FIGS. 11 and 12. Before performing the operation 25 and after performing the operation 24, in some embodiments, the method 20 may further include forming a sacrificial layer 207 on the low work function layer 206 by any suitable deposition method, for example, by a chemical vapor deposition method or a physical vapor deposition method. The sacrificial layer 207 is used to define a larger exposing space above the low work function layer 206 in the trench 202 after the sacrificial layer 207 is removed in the following operations, such that the larger exposing space helps to form the opening 209 in the operation 25 more easily. In some embodiments, the sacrificial layer 207 is formed on the whole upper surface of the low work function layer 206. In some embodiments, the sacrificial layer 207 is a metal nitride layer, for example, including titanium nitride, tantalum nitride, tungsten nitride, or combinations thereof.

In some embodiments, before performing the operation 25 and after performing the operation 24, the method 20 may further include forming a fifth part 203E of the isolation layer 203 on the second part 203B of the isolation layer 203 and above the low work function layer 206 by any suitable deposition method, for example, by a chemical vapor deposition or a physical vapor deposition. In addition to providing the electrical isolation, the fifth part 203E of the isolation layer 203 disposed above the low work function layer 206 increases the thickness of the isolation layer 203 above the low work function layer 206, thereby decreasing the electrical fields located between the word line and other components that may be disposed above the low work function layer 206. Moreover, a thicker isolation layer 203 above the low work function layer 206 can prevent the isolation layer 203 from being consumed too much in the following operations when forming other components in the trench 202 and above the low work function layer 206. In some embodiments, the fifth part 203E of the isolation layer 203 is formed on the sacrificial layer 207 after the sacrificial layer 207 is formed, as shown in FIG. 12.

In some embodiments, forming the fifth part 203E of the isolation layer 203 includes forming an extension portion 203E′ of the fifth part 203E of the isolation layer 203 on an upper surface of the sacrificial layer 207, and in some embodiments, the fifth part 203E of the isolation layer 203 covers the whole upper surface of the sacrificial layer 207. In some embodiments, the fifth part 203E of the isolation layer 203 is conformally formed along the exposed surfaces of the second part 203B of the isolation layer 203 and the sacrificial layer 207. In some embodiments, the fifth part 203E of the isolation layer 203 is formed further on the second part 203B of the isolation layer 203 on the first part 203A of the isolation layer 203 outside the trench 202 (not drawn). In some embodiments, the fifth part 203E of the isolation layer 203 includes a dielectric material, for example, silicon oxide, silicon nitride, or a combination thereof.

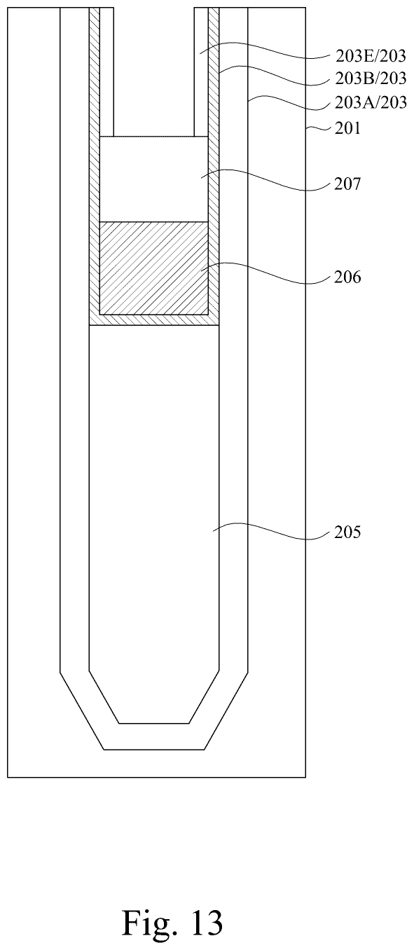

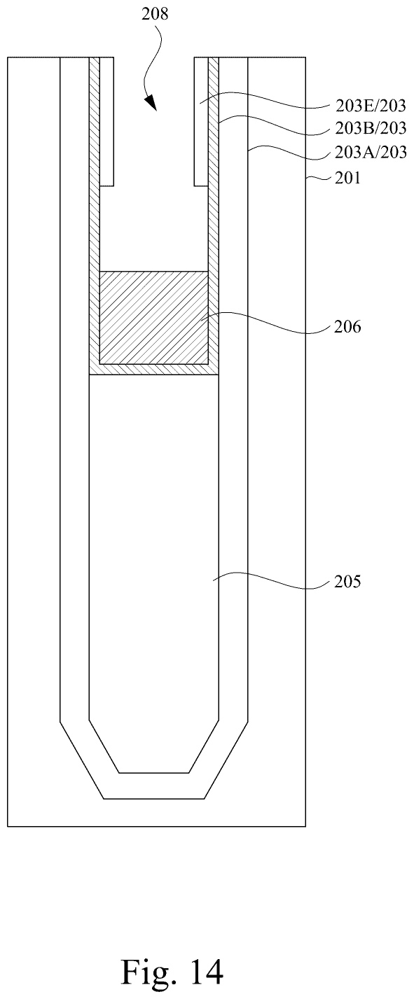

See FIGS. 13 and 14. Before performing the operation 25 and after forming the fifth part 203E of the isolation layer 203, in some embodiments, the method 20 may further include removing the sacrificial layer 207 by a wet etching method to form the larger exposing space above the low work function layer 206 in the trench 202. Compared with not forming the sacrificial layer 207 and directly contacting the fifth part 203E of the isolation layer 203 to the low work function layer 206 (not drawn), forming the sacrificial layer 207, forming the fifth part 203E of the isolation layer 203, and removing the sacrificial layer 207 in sequence can ensure that after the sacrificial layer 207 is removed, a larger portion of the upper surface of the low work function layer 206 is exposed for an easier formation of the opening 209 in the operation 25. In some embodiments, before removing the sacrificial layer 207, the method 20 may further include removing the extension portion 203E′ of the fifth part 203E of the isolation layer 203 by an anisotropic etching method, for example, by a try etching method. In some embodiments, after removing the sacrificial layer 207, an opening 208 with an inverted T-shaped cross-section on the low work function layer 206 is formed.

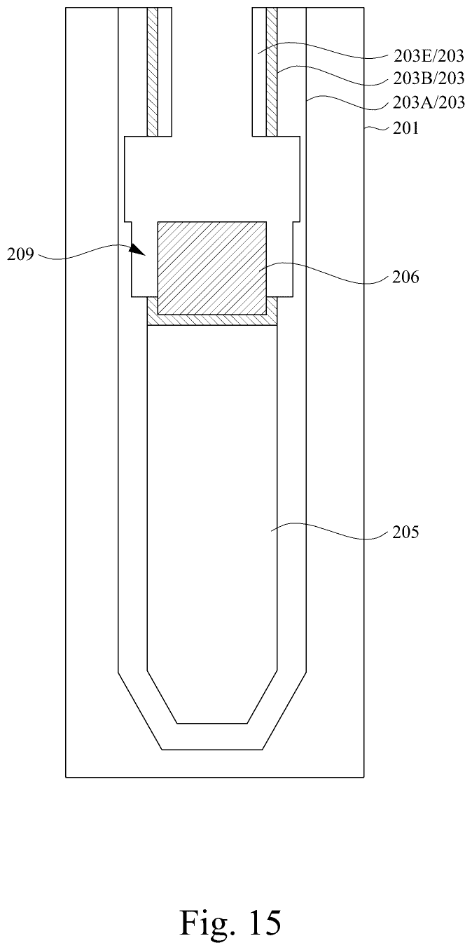

See FIG. 15. The operation 25 includes etching the portion of the second part 203B of the isolation layer 203 above and beside the low work function layer 206 to form an opening beside the low work function layer 206, and in some embodiments the operation 25 further includes etching the portion of the first part 203A of the isolation layer 203 above and beside the low work function layer 206 to form the opening 209 beside the low work function layer 206. In some embodiments, the operation 25 is performed by an isotropic etching method, for example, by a wet etching method. In the embodiments that the fifth part 203E of the isolation layer 203 is formed directly contacting the low work function layer 206 (not drawn), a portion of the third part 203C of the isolation layer 203 above and beside the low work function layer 206 is also etched together in the operation 25 to form the opening beside the low work function layer 206. In some embodiments, the etching in the operation 25 is performed through the opening 208 with the inverted T-shaped cross-section described above to help form the opening (e.g., the opening 209) more easily. In some embodiments, the opening (e.g., the opening 209) formed in the operation 25 exposes the whole upper surface and at least a portion of the side surface of the low work function layer 206. In some embodiments, the opening (e.g., the opening 209) formed in the operation 25 exposes the whole side surface of the low work function layer 206 (not drawn). In some embodiments, the opening (e.g., the opening 209) formed in the operation 25 is between the low work function layer 206 and the isolation layer 203. In some embodiments, the opening (e.g., the opening 209) formed in the operation 25 has a step-like side surface away from the low work function layer 206 and in contact with the isolation layer 203. In some embodiments, after performing the operation 25, only a portion of the first part 203A of the isolation layer 203 beside the opening 209 is remained (or the opening 209 exposes the first part 203A) to favor the reaction in the operation 26 to perform more easily. In some embodiments, after performing the operation 25, the second part 203B of the isolation layer 203 is separated from the upper surface of the low work function layer 206, and a virtual extension line of the boundary of a portion of the second part 203B of the isolation layer 203 disposed above the low work function layer 206 is aligned with the side surface of the low work function layer 206.

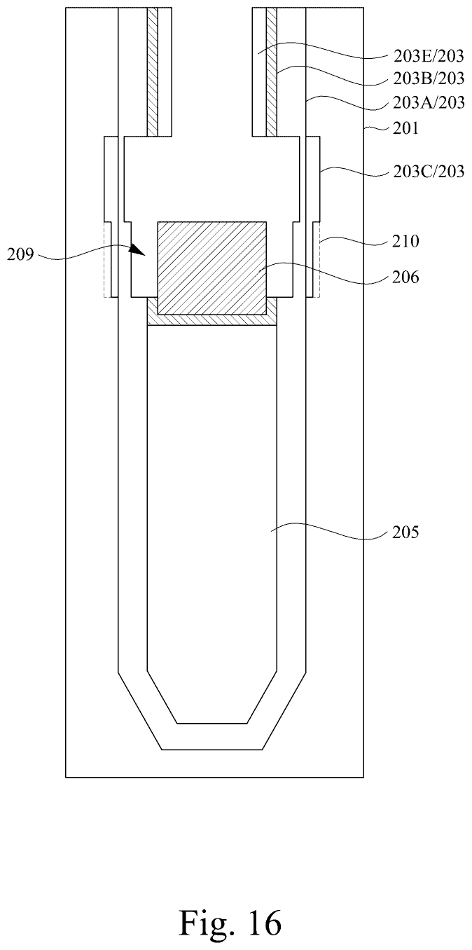

See FIGS. 15 and 16. The operation 26 includes oxidizing the portion of the substrate 201 beside the opening (e.g., the opening 209) formed in the operation 25 to transform the portion of the substrate 201 into the third part 203C of the isolation layer 203. When the portion of the substrate 201 is oxidized, it becomes a part of the isolation layer 203 to provide the electrical isolation. For example, when the substrate 201 is a silicon substrate, the silicon can be oxidized to become silicon oxide to provide the electrical isolation. Moreover, after transforming the portion of the substrate 201 into the third part 203C of the isolation layer 203, the portion of the isolation layer 203 beside the low work function layer 206 extends into the substrate 201 to form the isolation layer 203 having a thicker thickness beside the low work function layer 206 in the following operations. In some embodiments, oxidizing the portion of the substrate 201 is performed by flowing oxygen and hydrogen into the opening (e.g., the opening 209) formed in the operation 25 to react with the portion of the substrate 201 to form the third part 203C of the isolation layer 203. In some embodiments, oxidizing the portion of the substrate 201 is performed by a temperature preferably from 400° C. to 900° C., for example, 400° C., 500° C., 600° C., 700° C., 800° C., or 900° C. In some embodiments, oxidizing the portion of the substrate 201 is performed by an in situ steam generation (ISSG) method. In some embodiments, after performing the operation 26, the third part 203C of the isolation layer 203 has a step-like side surface facing the substrate 201 and in contact with the substrate 201. In some embodiments, after performing the operation 26, the third part 203C of the isolation layer 203 has a straight side surface (shown by the dashed line 210 in FIG. 16, as described in the embodiments of FIGS. 2C and 2D) facing the substrate 201 and in contact with the substrate 201.

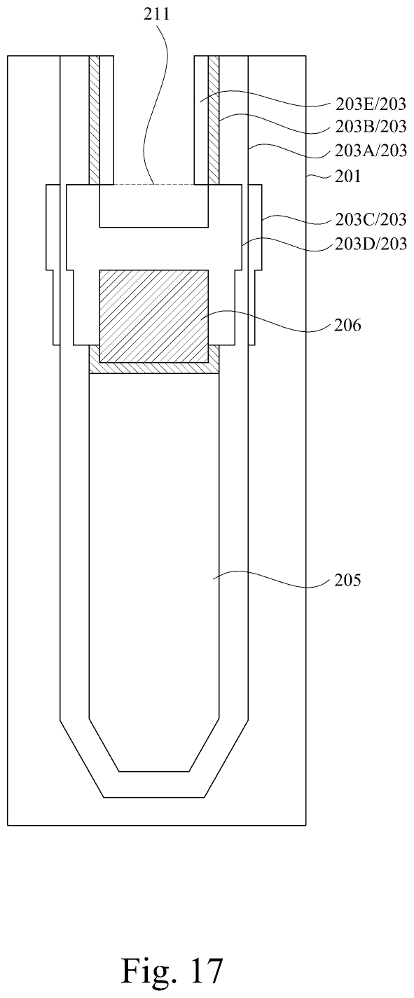

See FIGS. 16 and 17. The operation 27 includes filling the fourth part 203D of the isolation layer 203 in the opening (e.g., the opening 209) formed in the operation 25. In addition to providing the electrical isolation, the fourth part 203D of the isolation layer 203 increases the thickness of the isolation layer 203 beside the low work function layer 206, such that the thickness T2 of the portion of the isolation layer 203 beside the low work function layer 206 is larger than the thickness T1 of the portion of the isolation layer 203 beside the high work function layer 205, thereby reducing the gate-induced drain leakage. In some embodiments, the fourth part 203D of the isolation layer 203 includes a dielectric material, for example, silicon oxide, silicon nitride, or a combination thereof. In some embodiments, the operation 27 is performed by an atomic layer deposition (ALD) method. In some embodiments, filling the fourth part 203D of the isolation layer 203 includes filling the fourth part 203D of the isolation layer 203 on the whole upper surface of the low work function layer 206. In some embodiments, after performing the operation 27, the fourth part 203D of the isolation layer 203 is separated from the fifth part 203E of the isolation layer 203 to form the semiconductor structure as shown in FIG. 2A or FIG. 2C. In some embodiments, after performing the operation 27, the fourth part 203D of the isolation layer 203 is in contact with the fifth part 203E of the isolation layer 203 to form the semiconductor structure as shown in FIG. 2B or FIG. 2D, and a dashed line 211 is shown in FIG. 17 for a boundary of the fourth part 203D of the isolation layer 203.

See FIG. 18. In some embodiments, the method 20 may further include forming a nitride layer 212 on the fifth part 203E of the isolation layer 203 after filing the fourth part 203D of the isolation layer 203 in the opening (e.g., the opening 209) formed in the operation 25, in which a thickness T3 of a portion of the isolation layer 203 including the fifth part 203E of the isolation layer 203 beside the nitride layer 212 is larger than the thickness T1 of the portion of the isolation layer 203 beside the high work function layer 205. In some embodiments, the method 20 may further include forming a cell contact (not drawn) and a bit line (not drawn) on the substrate 201 above the word line. In some embodiments, the method 20 further includes forming a source (not drawn) and a drain (not drawn) respectively on the two sides of the gate of the word line. After forming the nitride layer 212 and in some embodiments after forming the cell contact, the bit line, the source, and the drain, the semiconductor structure described in FIGS. 1 to 3 is formed, and the features of the semiconductor structure may be referred to in the description above and may not be repeated herein. For example, the substrate 201, the word line including the high work function layer 205 and the low work function layer 206, the isolation layer 203, and the nitride layer 212 are substantially the same as the substrate 101, the word line 102 including the high work function layer 102H and the low work function layer 102L, the dielectric layer 103, and the nitride layer 105 described above.

The semiconductor structure of the present disclosure and the semiconductor structure formed by the method of the present disclosure improve the performance of the word line. For example, the distances between the gate of the word line and the other components that may be disposed above the word line are receded to reduce the influence of the electrical fields located between the word line and the other components, thereby reducing the electrical fields interfering with the word line. The gate-induced drain leakage (GIDL) is reduced in the semiconductor structure. Without using the air gap to replace the dielectric material, the drop of the dielectric constant caused by the air gap is avoided to prevent reducing the control to the gate of the word line when operating the word line. The control to the gate of the word line is improved and the resistance of the word line is decreased.

The present disclosure is described in considerable detail in some embodiments, but other embodiments may also be feasible, so the description of the embodiments in the present disclosure is not intended to limit the scope and spirit of the claims attached. For one skilled in the art, the present disclosure may be modified and changed without deviating from the scope and spirit of the present disclosure. Such modifications and changes are intended to be covered by the present disclosure when they belong to the scope and spirit of the attached claims.

What is claimed is:

1. A semiconductor structure, comprising:
a substrate;
a word line embedded in the substrate and comprising a high work function layer and a low work function layer on the high work function layer, wherein a work function of the high work function layer is larger than a work function of the low work function layer; and
a dielectric layer between the substrate and the word line, wherein the dielectric layer comprises:
a first portion between the substrate and the high work function layer; and
a second portion between the substrate and the low work function layer, wherein a thickness of the second portion is larger than a thickness of the first portion.

2. The semiconductor structure of claim 1, wherein a curved boundary is between the high work function layer and the first portion, and the high work function layer extends toward the first portion at the curved boundary.

3. The semiconductor structure of claim 1, wherein compared to the first portion, the second portion extends farther into the substrate.

4. The semiconductor structure of claim 1, wherein the second portion has a step-like sidewall facing the substrate.

5. The semiconductor structure of claim 1, wherein the dielectric layer further comprises an extension portion between the high work function layer and the low work function layer.

6. The semiconductor structure of claim 1, wherein the dielectric layer further comprises an extension portion on an upper surface of the low work function layer.

7. The semiconductor structure of claim 1, further comprising a nitride layer embedded in the substrate and on the word line, wherein the dielectric layer further comprises a third portion between the substrate and the nitride layer, and a thickness of the third portion is larger than the thickness of the first portion.

8. The semiconductor structure of claim 7, wherein the third portion comprises a first layer on the substrate, a second layer on the first layer, and a third layer on the second layer, and a material of the second layer is different than materials of the first layer and the third layer.

9. The semiconductor structure of claim 7, wherein the third portion overlaps the word line from a top view.

10. The semiconductor structure of claim 7, wherein the nitride layer has a cross-section with an inverted T shape or a rectangular shape on the word line.

11. The semiconductor structure of claim 1, wherein the work function of the high work function layer is from 4.3 eV to 4.7 eV, and the work function of the low work function layer is from 4.0 eV to 4.4 eV.

12. A method of forming a semiconductor structure, comprising:
forming a first part of an isolation layer on a sidewall of a trench in a substrate;
forming a high work function layer in the trench and on the first part;
forming a second part of the isolation layer on the first part and the high work function layer;
forming a low work function layer on the high work function layer and the second part, wherein a work function of the high work function layer is larger than a work function of the low work function layer;
etching a portion of the second part and a portion of the first part beside the low work function layer to form an opening beside the low work function layer;
oxidizing a portion of the substrate beside the opening to transform the portion of the substrate into a third part of the isolation layer; and
filling a fourth part of the isolation layer in the opening, wherein a thickness of a portion of the isolation layer beside the low work function layer is larger than a thickness of a portion of the isolation layer beside the high work function layer.

13. The method of claim 12, wherein forming the second part further comprises forming an extension portion of the second part on an upper surface of the high work function layer, and forming the low work function layer comprises forming the low work function layer on the extension portion.

14. The method of claim 12, further comprising forming a fifth part of the isolation layer on the second part after forming the low work function layer and before etching the portion of the second part and the portion of the first part.

15. The method of claim 14, further comprising forming a nitride layer on the fifth part after filing the fourth part in the opening, wherein a thickness of a portion of the isolation layer including the fifth part and beside the nitride layer is larger than the thickness of the portion of the isolation layer beside the high work function layer.

16. The method of claim 14, further comprising:
forming a sacrificial layer on the low work function layer after forming the low work function layer and before forming the fifth part, wherein forming the fifth part further comprises forming an extension portion of the fifth part on an upper surface of the sacrificial layer; and
removing the extension portion and the sacrificial layer to form an opening with an inverted T-shaped cross-section on the low work function layer before etching the portion of the second part and the portion of the first part.

17. The method of claim 12, wherein filling the fourth part comprises filling the fourth part on an upper surface of the low work function layer.

18. The method of claim 12, further comprising etching a portion of the first part before forming the high work function layer.

19. The method of claim 12, wherein a material of the first part and a material of the second part are different.

20. The method of claim 12, wherein a material of the first part and a material of the second part are the same.
